(19) United States
(12) Patent Application Publication
(10) Pub. No.: US 2010/0232229 A1
(43) Pub. Date: Sep. 16, 2010

(54) SEMICONDUCTOR MEMORY DEVICE INCLUDING STACKED GATE INCLUDING CHARGE ACCUMULATION LAYER AND CONTROL GATE

(76) Inventors: Takeshi OGAWA, Kawasaki-shi (JP); Yoshihisa Watanabe, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/722,052

(22) Filed: Mar. 11, 2010

(30) Foreign Application Priority Data
Mar. 12, 2009 (JP) 2009-059732

(51) Int. Cl. G11C 16/06

(52) U.S. Cl. 365/185.21; 365/185.23

(57) ABSTRACT

A semiconductor memory device includes a memory cell, a bit line, a source line, a source line driver, a sense amplifier, a counter, a detector, a controller. The sense amplifier reads the data by sensing current flowing through the bit line. The counter counts ON memory cells and/or OFF memory cells. The detector detects whether the voltage of the source line has exceeded a reference voltage. The controller controls the number of times of data sensing by the sense amplifier in accordance with the detection result in the detector, and controls a driving force of the source line driver in accordance with the count in the counter.

### CROSS-REFERENCE TO RELATED APPLICATIONS

This application is based upon and claims the benefit of priority from prior Japanese Patent Application No. 2009-059732, filed Mar. 12, 2009, the entire contents of which are incorporated herein by reference.

### BACKGROUND OF THE INVENTION

1. Field of the Invention

The present invention relates to a semiconductor memory device such as a NAND flash memory.

2. Description of the Related Art

A NAND flash memory is conventionally known as a nonvolatile semiconductor memory. Also, a method of sensing a current is known as a NAND flash memory data read method. This method is disclosed in, e.g., JP-A 2006-500727 (KOHYO).

This method reduces the influence of noise between bit lines by keeping the bit line potential constant. However, a cell current must be kept supplied from a bit line to a source line in order to keep the bit line potential constant. Consequently, the total cell current becomes very large, and this may worsen the reliability of the product.

### BRIEF SUMMARY OF THE INVENTION

A semiconductor memory device according to an aspect of the present invention includes:

a memory cell including a charge accumulation layer and a control gate, and configured to hold data;

a bit line electrically connected to a drain of the memory cell;

a source line electrically connected to a source of the memory cell;

a source line driver which applies a voltage to the source line;

a sense amplifier which reads the data by sensing current flowing through the bit line in a read operation and/or a verify operation of the data;

a counter which counts ON memory cells and/or OFF memory cells in the read operation and/or the verify operation;

a detector which detects whether the voltage of the source line has exceeded a reference voltage, in the read operation and/or the verify operation; and

a controller which controls the number of times of data sensing by the sense amplifier in accordance with the detection result in the detector, and controls a driving force of the source line driver in accordance with the count in the counter.

### BRIEF DESCRIPTION OF THE SEVERAL VIEWS OF THE DRAWING

FIG. 1 is a block diagram of a flash memory according to the first embodiment of the present invention;

FIG. 2 is a block diagram of a partial region of the flash memory according to the first embodiment;

FIG. 3 is a sectional view of a memory cell unit according to the first embodiment;

FIG. 4 is a graph showing the threshold value distribution of a memory cell according to the first embodiment;

FIGS. 5 and 6 are respectively circuit diagrams of a sense amplifier and the memory cell unit according to the first embodiment;

FIG. 7 is a flowchart showing the operation of the flash memory according to the first embodiment;

FIG. 8 is a timing chart of various voltages in the first embodiment;

FIG. 9 is a flowchart showing the operation of a flash memory according to the second embodiment of the present invention;

FIG. 10 is a graph showing the relationship between the ON cell count and the source line voltage in the second embodiment;

FIG. 11 is a flowchart showing the operation of a flash memory according to the third embodiment of the present invention;

FIG. 12 is a graph showing the relationship between the ON cell count and the source line voltage in the third embodiment;

FIG. 13 is a flowchart showing the operation of a flash memory according to the fourth embodiment of the present invention;

FIG. 14 is a graph showing the relationship between the ON cell count and the source line voltage in the fourth embodiment;

FIG. 15 is a flowchart showing the operation of a flash memory according to the fifth embodiment of the present invention;

FIG. 16 is a graph showing the relationship between the ON cell count and the source line voltage in the fifth embodiment;

FIG. 17 is a flowchart showing the operation of a flash memory according to the sixth embodiment of the present invention;

FIG. 18 is a graph showing the relationship between the ON cell count and the source line voltage in the sixth embodiment;

FIG. 19 is a flowchart showing the operation of a flash memory according to the seventh embodiment of the present invention;

FIG. 20 is a graph showing the relationship between the ON cell count and the source line voltage in the seventh embodiment;

FIG. 21 is a circuit diagram of a source line driver according to the eighth embodiment of the present invention;

FIG. 22 is a timing chart of various voltages in the eighth embodiment;

FIG. 23 is a circuit diagram of a source line driver according to the eighth embodiment;

FIG. 24 is a timing chart of various voltages in the eighth embodiment; and

FIG. 25 is a circuit diagram of a source line driver according to the eighth embodiment.

### DETAILED DESCRIPTION OF THE INVENTION

### First Embodiment

A semiconductor memory device according to the first embodiment of the present invention will be explained below by taking a NAND flash memory as an example.

### <Configuration of NAND Flash Memory>

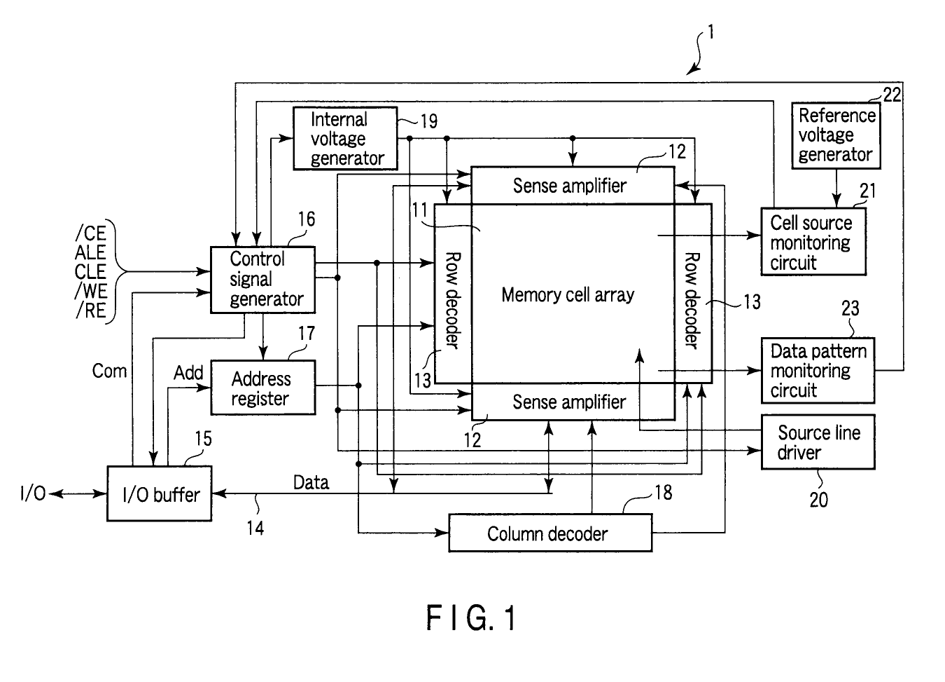

FIG. 1 is a block diagram of a NAND flash memory according to the first embodiment of the present invention. As shown in FIG. 1, a NAND flash memory 1 includes a memory cell array 11, sense amplifiers 12, row decoders 13, a data bus 14, an I/O buffer 15, a control signal generator 16, an address register 17, a column decoder 18, an internal voltage generator 19, a source line driver 20, a cell source monitoring circuit 21, a reference voltage generator 22, and a data pattern monitoring circuit 23.

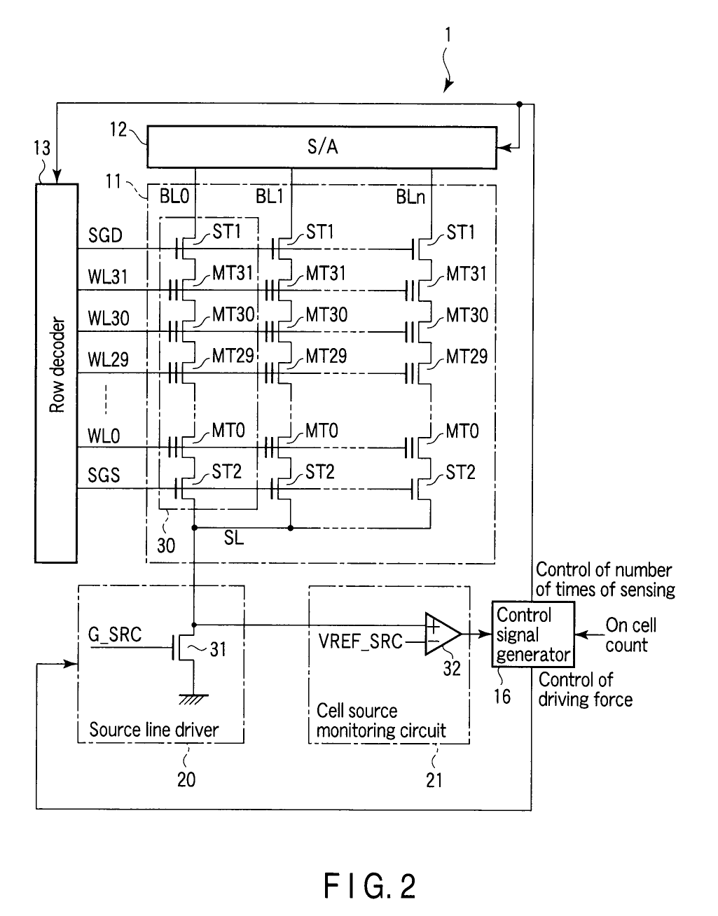

First, the memory cell array 11 will be explained below with reference to FIG. 2. FIG. 2 is a block diagram showing details of the memory cell array 11, sense amplifier 12, row decoder 13, control signal generator 16, source line driver 20, and cell source monitoring circuit 21.

As shown in FIG. 2, the memory cell array 11 includes a plurality of memory cell units 30. Each memory cell unit 30 includes, e.g., 32 memory cell transistors MT0 to MT31, and select transistors ST1 and ST2. The memory cell transistors MT0 to MT31 will be collectively called memory cell transistors MT when it is unnecessary to distinguish between them. The memory cell transistor MT has a stacked gate structure including a charge accumulation layer (e.g., a floating gate) formed on a semiconductor substrate with a gate insulating film interposed therebetween, and a control gate formed on the charge accumulation layer with an inter-gate insulating film interposed therebetween. Note that the number of the memory cell transistors MT is not limited to 32, and may also be, e.g., 8, 16, 64, 128, or 256. That is, the number of the memory cell transistors MT is not particularly limited. Adjacent memory cell transistors MT share the source and drain. The memory cell transistors MT are arranged between select transistors ST1 and ST2 such that the current paths of the memory cell transistors MT are connected in series. The drain at one end of the series-connected memory cell transistors MT is connected to the source of select transistor ST1, and the source at the other end is connected to the drain of select transistor ST2.

The control gates of the memory cell transistors MT in the same row are connected together to one of word lines WL0 to WL31. The gates of select transistors ST1 in the same row are connected together to a select gate line SGD, and those of select transistors ST2 in the same row are connected together to a select gate line SGS. Note that for the sake of simplicity, the word lines WL0 to WL31 will simply be called word lines WL in some cases hereinafter). The drain of select transistor ST1 is connected to one of bit lines BL0 to BLn (n is a natural number). The bit lines BL0 to BLn will also simply be called bit lines BL in some cases. The sources of select transistors ST2 are connected together to a source line SL. Note that the two select transistors ST1 and ST2 need not always be necessary, and only one of them may also be formed as long as the memory cell unit 30 can be selected.

FIG. 2 shows only one row of the memory cell units 30. However, a plurality of rows (in the vertical direction of FIG. 2) of the memory cell units 30 may also be formed in the memory cell array 11. In this case, the memory cell units 30 in the same column are connected to the same bit line BL. Also, data are simultaneously written in a plurality of memory cell transistors MT connected to the same word line WL. This unit will be called a page. In addition, data in a plurality of memory cell units 30 in the same row are simultaneously erased. This unit will be called a memory block.

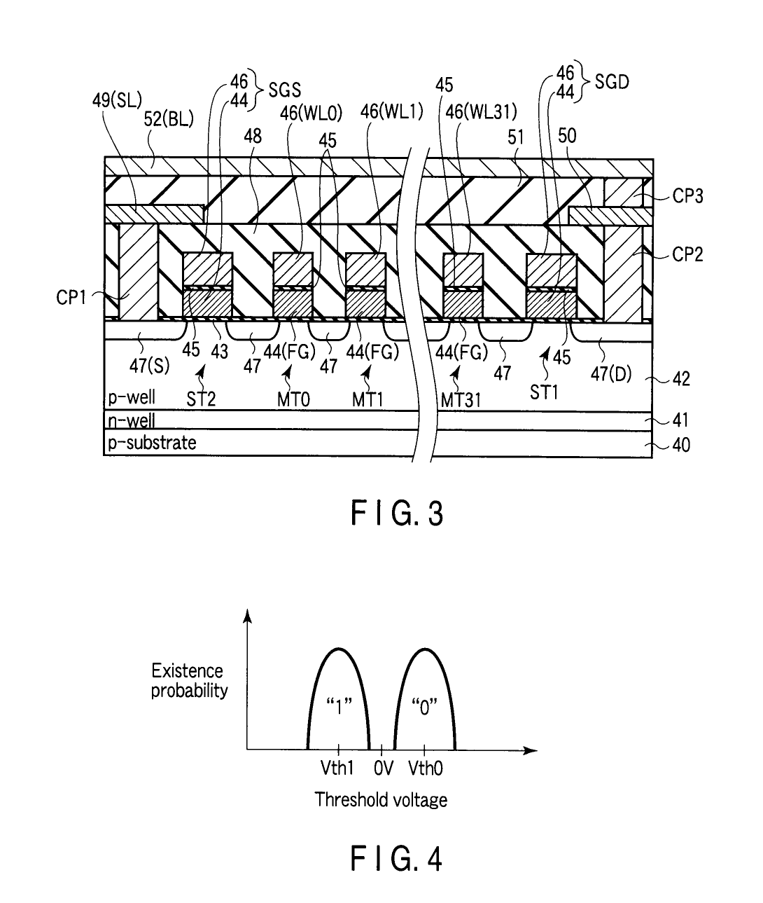

The arrangement of the memory cell unit 30 of the memory cell array 11 described above will be explained below with reference to FIG. 3. FIG. 3 is a sectional view of the memory cell unit 30 in the bit line direction.

As shown in FIG. 3, an n-type well region 41 is formed in the surface region of a p-type semiconductor substrate 40, and a p-type well region 42 is formed in the surface region of the n-type well region 41. A gate insulating film 43 is formed on the p-type well region 42. The gate electrodes of the memory cell transistors MT and select transistors ST1 and ST2 are formed on the gate insulating film 43. The gate electrodes of the memory cell transistors MT and select transistors ST1 and ST2 each include a polysilicon layer 44 formed on the gate insulating film 43, an inter-gate insulating film 45 formed on the polysilicon layer 44, and a polysilicon layer 46 formed on the inter-gate insulating film 45. The inter-gate insulating film 45 is made of, for example, a silicon oxide film, an ON film, NO film, or ONO film as a stacked structure including a silicon oxide film and silicon nitride film, a stacked structure including the ON film, NO film, or ONO film, or a stacked structure including TiO₂, HfO₂, Al₂O₃, HfAlOₓ, or HfAlSi film and a silicon oxide film or silicon nitride film. The gate insulating film 43 functions as a tunnel insulating film.

In the memory cell transistor MT, the polysilicon layer 44 functions as a floating gate (FG). On the other hand, the polysilicon layers 46 adjacent to each other in a direction perpendicular to the bit line are connected together and function as the control gate (word line WL). In the select transistors ST1 and ST2, the polysilicon layers 44 and 46 adjacent to each other in the word line direction are connected together. The polysilicon layers 44 and 46 function as the select gate lines SGS and SGD. Note that the polysilicon layer 44 alone can also function as the select gate line. In this case, the potential of the polysilicon layers 46 of select transistors ST1 and ST2 is held constant or floated. N⁺-type impurity diffusion layers 47 are formed in those portions of the surface of the semiconductor substrate 40, which are positioned between the gate electrodes. The impurity diffusion layer 47 is shared by adjacent transistors, and functions as the source (S) or drain (D). A region between the source and drain adjacent to each other functions as a channel region serving as a region where electrons move. The gate electrodes, impurity diffusion layers 47, and channel regions form MOS transistors serving as the memory cell transistors MT and the select transistors ST1 and ST2.

An interlayer dielectric film 48 is formed on the semiconductor substrate 40 so as to cover the memory cell transistors MT and the select transistors ST1 and ST2 described above. A contact plug CP1 reaching the impurity diffusion layer (source) 47 of select transistor ST2 on the source side is formed in the interlayer dielectric film 48. A metal interconnection layer 49 connected to contact plug CP1 is formed on the interlayer dielectric film 48. The metal interconnection layer 49 functions as a part of the source line SL. A contact plug CP2 reaching the impurity diffusion layer (drain) 47 of select transistor ST1 on the drain side is also formed in the interlayer dielectric film 48. A metal interconnection layer 50 connected to contact plug CP2 is formed on the interlayer dielectric film 48.

An interlayer dielectric film 51 is formed on the interlayer dielectric film 48 so as to cover the metal interconnection layers 49 and 50. A contact plug CP3 reaching the metal interconnection layer 50 is formed in the interlayer dielectric film 51. A metal interconnection layer 52 connected to a plurality of contact plugs CP3 is formed on the interlayer dielectric film 51. The metal interconnection layer 52 functions as the bit line BL.

The threshold value distribution of the memory cell transistor MT described above will be explained below with reference to FIG. 4. FIG. 4 is a graph showing the existence probability of the memory cell transistor MT on the ordinate by plotting a threshold voltage Vth on the abscissa.

As shown in FIG. 4, each memory cell transistor MT can hold binary (2-level) data (1-bit data). That is, the memory cell transistor MT can hold two kinds of data, i.e., binary 1 and binary 0 in ascending order of the threshold voltage Vth. In the memory cell transistor MT, a threshold voltage Vth1 of binary 1 has a negative value (Vth1<0), and a threshold voltage Vth0 of binary 0 has a positive value (0<Vth0).

Note that data that can be held by the memory cell transistor MT is not limited to the above-mentioned binary data. For example, the data may also be quaternary data (2-bit data), octernary data (3-bit data), or hexadecimal data (4-bit data).

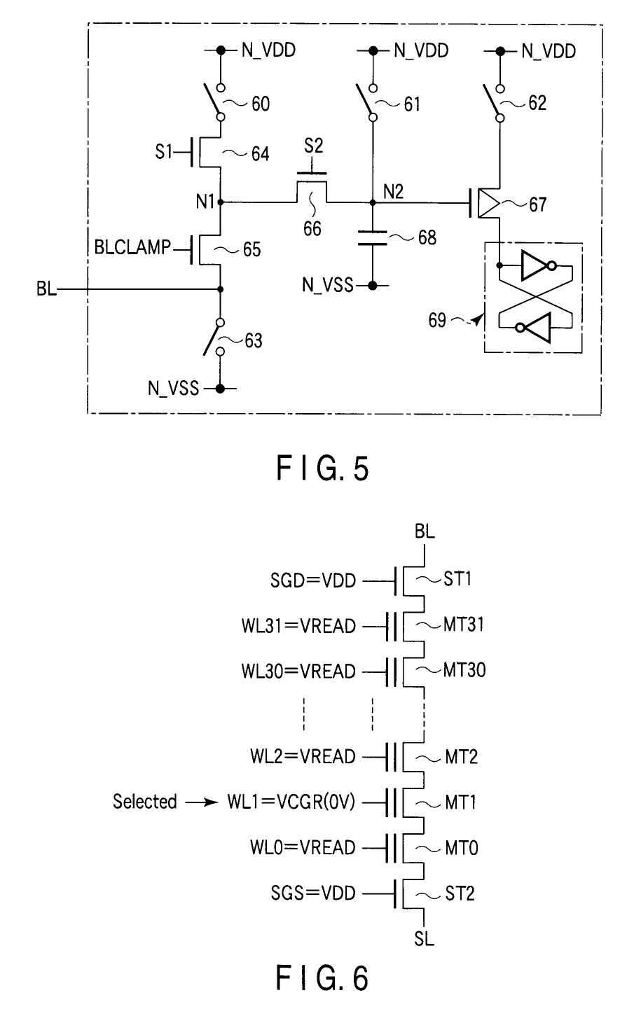

Referring to FIG. 1 again, in data read and verify, the sense amplifier 12 senses and amplifies data read from the memory cell transistor MT to the bit line BL. In data write, the sense amplifier 12 transfers write data to the bit line BL. The arrangement of the sense amplifier 12 will be explained below with reference to FIG. 5. FIG. 5 is a circuit diagram of the sense amplifier 12 corresponding to one bit line BL. That is, the arrangement shown in FIG. 5 is formed for each bit line BL.

As shown in FIG. 5, the sense amplifier 12 includes switching elements 60 to 63, n-channel MOS transistors 64 to 66, a p-channel MOS transistor 67, a capacitor element 68, and a latch circuit 69. The current path of MOS transistor 64 has one end connected to a node N_VDD via the switching element 60, and the other end connected to a node N1. A signal S1 is input to the gate of MOS transistor 64. The current path of MOS transistor 65 has one end connected to node N1, and the other end connected to a node N_VSS via the bit line BL and switching element 63. A signal BLCLAMP is supplied to the gate of MOS transistor 65. The switching element 63 connects the bit line BL to node N_VSS in accordance with data held by the latch circuit 69. The current path of MOS transistor 66 has one end connected to node N1, and the other end connected to a node N2. A signal S2 is supplied to the gate of MOS transistor 66. Node N2 is connected to node N_VDD via the switching element 61. The capacitor element 68 has one electrode connected to node N2, and the other electrode connected to node N_VSS. The current path of MOS transistor 67 has one end connected to node N_VDD via the switching element 62, and the other end connected to the latch circuit 69. The gate of MOS transistor 67 is connected to node N2.

Note that node N_VDD functions as a power supply voltage node of the sense amplifier 12, and a voltage VDD (e.g., 1.5 V) is applied to node N_VDD. The voltage VDD is the internal power supply of the flash memory 1. Note also that node N_VSS functions as a ground node of the sense amplifier 12, and has a voltage VSS (e.g., ground potential [0 V]).

As shown in FIG. 2, the sense amplifiers 12 are formed at the two ends of the memory cell array 11 in the bit line direction. The circuit unit shown in FIG. 5 included in one sense amplifier 12 is connected to, e.g., even-numbered bit lines BL0, BL2, BL4, . . . , and the circuit unit shown in FIG. 5 included in the other sense amplifier 12 is connected to, e.g., odd-numbered bit lines BL1, BL3, BL5, . . . .

Referring to FIG. 1 again, in data write, read, and erase operations, the row decoder 13 performs selection in the row direction of the memory cell array 11. That is, the row decoder 13 applies voltages to the select gate lines SGD and SGS and word lines WL. As shown in FIG. 1, the row decoders 13 are formed at the two ends of the memory cell array 11 in the word line direction. One end of each of the word lines WL and select gate lines SGD and SGS is connected to one row decoder 13, and the other end of each of the word lines WL and select gate lines SGD and SGS is connected to the other row decoder 13.

The row decoders 13 perform operations of selecting the select gate lines SGD and SGS and word lines WL, and applies voltages necessary for the operations. The row decoders 13 also apply a necessary voltage to the p-type well region 42 in which the memory cell unit 30 is formed. When erasing data, for example, the row decoders 13 apply 0 V to all the word lines WL, and a positive voltage (e.g., 20 V) to the well region 42. Consequently, electrons in the charge accumulation layer 44 are extracted to the well region 42, thereby erasing the data. A programming operation, read operation, and verify operation of data will be explained in detail later.

The source line driver 20 applies a voltage to the source line SL. As shown in FIG. 2, the source line driver 20 includes an n-channel MOS transistor 31. MOS transistor 31 has the drain connected to the source line SL, the source that is grounded, and the gate to which a signal G_SRC is input. When MOS transistor 31 is turned on, ground potential is applied to the source line SL.

The cell source monitoring circuit 21 monitors the potential of the source line SL. As shown in FIG. 2, the cell source monitoring circuit 21 includes, e.g., an operational amplifier 32. The source line SL is connected to a non-inverting input terminal (+) of the operational amplifier 32, and a reference voltage VREF_SRC is applied to an inverting input terminal (−). The operational amplifier 32 performs comparison and amplification on the potential of the source line SL and the reference voltage VREF_SRC, and outputs the result to the control signal generator 16.

Referring to FIG. 1 again, the reference voltage generator 22 generates the reference voltage VREF_SRC, and outputs the generated voltage to the cell source monitoring circuit 21.

In the data verify operation, the data pattern monitoring circuit 21 counts memory cell transistors MT having passed the verify and/or memory cell transistors MT having failed the verify, based on the sensing/amplification results in the sense amplifier 12. In other words, the data pattern monitoring circuit 21 counts OFF memory cell transistors MT (this count will be called the OFF cell count in some cases) and/or ON memory cell transistors MT (this count will be called the ON cell count in some cases). The data pattern monitoring circuit 21 outputs the counts to the control signal generator 16. Also, the data pattern monitoring circuit 21 performs the same operation in data read.

The column decoder 18 performs selection in the column direction of the memory cell array 11.

In the read operation, the I/O buffer 15 temporarily holds data read by the sense amplifier 12, and outputs the data outside from the I/O terminal. In the write operation, the I/O buffer 15 temporarily holds data externally supplied via the I/O terminal, and transfers the data to the sense amplifier 12. The I/O buffer 15 and sense amplifier 12 exchange data via the data line 14. Also, the I/O buffer 15 temporarily holds signals externally supplied via the I/O terminal. Of the held signals, the I/O buffer 15 transfers an address Add to the address register 17, and a command Com to the control signal generator 16.

Of the received address Add, the address register 17 transfers the row address to the row decoder 13, and the column address to the column decoder 18. Based on the row address and column address, the row decoder 13 and column decoder 18 perform the selecting operations.

The internal voltage generator 19 generates voltages required for the read operation, write operation, and erase operation, based on instructions from the control signal generator 16. That is, the internal voltage generator 19 includes, e.g., a boosting circuit, and boosts the power supply voltage by using the boosting circuit, thereby generating necessary voltages (e.g., VPGM and VPASS). The internal voltage generator 19 applies the generated voltages to the sense amplifiers 12 and row decoders 13.

The control signal generator 16 receives various external control signals, and controls the overall operation of the NAND flash memory 1 based on the control signals. The external control signals include, e.g., a chip enable signal /CE, an address latch enable signal ALE, a command latch enable signal CLE, a write enable signal /WE, a read enable signal /RE, and the command Com. The chip enable signal /CE enables the whole of the NAND flash memory 1. The address latch enable signal ALE gives an instruction to latch the address Add. The command latch enable signal CLE gives an instruction to latch the command Com. The write enable signal /WE gives an instruction to perform a write operation. The read enable signal /RE gives an instruction to perform a read operation.

Based on these signals, the control signal generator 16 identifies whether the signal held in the I/O buffer 15 is the address Add or command Com, and instructs the I/O buffer 15 to transfer the signal. The control signal generator 16 also instructs the address register 17 to respectively transfer the row address and column address to the row decoder 13 and column decoder 18. Furthermore, the control signal generator 16 instructs the internal voltage generator 19 to generate necessary voltages.

In the read operation and verify operation, the control signal generator 16 receives the result of the comparison between the voltage of the source line SL and the reference voltage VREF_SRC from the cell source monitoring circuit 21, and receives the counts of passed cells and/or failed cells from the data pattern monitoring circuit 23. The control signal generator 16 controls the number of times of data read (the number of times of sensing) in the sense amplifier 12, and the driving force of the source line driver 20. This point will be explained in detail below.

### <Operations of NAND Flash Memory 1>

The operations of the NAND flash memory 1 having the above configuration will be explained below.

### <Write Operation>

First, the data write operation will be explained. Data is written by repeating a programming operation and verify operation. The programming operation is an operation of injecting electrons into the charge accumulation layer by applying a high voltage across the word line WL and the channel, thereby changing the threshold value of the memory cell transistor MT to the positive direction. The verify operation is an operation of checking whether the threshold value of the memory cell transistor MT is set at a desired value by the programming operation, i.e., whether data is correctly written. The write operation is performed by the repetition of programming→verify→programming→verify→ . . . . The voltage VPGM applied to a selected word line WL is stepped up whenever this repetition is performed.

### <<Programming Operation>>

First, the data programming operation will be explained with reference to FIG. 2. When programming data, the sense amplifier 12 transfers the program data to the bit line BL. That is, when increasing the threshold value of the memory cell transistor MT by injecting electrons into the charge accumulation layer, the sense amplifier 12 applies a write voltage (e.g., 0 V) to the bit line BL. On the other hand, the sense amplifier 12 applies a write inhibit voltage (e.g., VDD) when injecting no electrons. The source line driver 20 and row decoder 13 respectively apply 0 V to the source line SL and well region 42.

The row decoder 13 selects one word line WL, and applies the voltage VPGM to the selected word line. Also, the row decoder 13 applies the voltage VPASS to other word lines WL (unselected word lines WL). The voltage VPGM is a high voltage (e.g., about 20 V) for injecting electrons into the charge accumulation layer by FN (Fowler-Nordheim) tunneling. The voltage VPASS turns on the memory cell transistor MT regardless of data to be held. In addition, the row decoder 13 applies 0 V to the select gate line SGS, and a voltage VSGD to the select gate line SGD. The voltage VSGD turns on select transistor ST1 when the write voltage is applied to the bit line BL, and cuts off select transistor ST1 when the write inhibit voltage is applied to the bit line BL.

In the memory cell unit 30 in which the write voltage (0 V) is applied to the bit line BL, select transistor ST1 is turned on, and the write voltage is transferred to the channel of the memory cell transistor MT. In the memory cell transistor MT connected to the selected word line WL, the potential difference between the gate and the channel becomes almost equal to VPGM, so a charge is injected into the charge accumulation layer. As a consequence, the threshold voltage of the memory cell transistor MT rises.

On the other hand, when the write inhibit voltage (VDD) is applied to the bit line BL, select transistor ST1 is cut off. Accordingly, the channel of the memory cell transistor MT in the memory cell unit 30 electrically floats. This raises the channel potential of the memory cell transistor MT by coupling with the gate potential (VPGM or VPASS). In the memory cell transistor MT connected to the selected word line WL, therefore, the potential difference between the gate and the channel is insufficient, and an insufficient charge is injected into the charge accumulation layer (i.e., the held data does not transit). Consequently, the threshold value of the memory cell transistor MT remains unchanged.

### <<Verify Operation>>

The verify operation will now be explained. FIG. 6 is a circuit diagram of the memory cell unit 30 when reading data. The operation will be explained below by taking verify performed on the memory cell transistor MT connected to the word line WL1 as an example.

First, the sense amplifier 12 precharges all the bit lines BL. The row decoder 13 applies 0 V to the well region 42. Since signal G_SRC is made high (“H” level), MOS transistor 31 of the source line driver 20 is turned on to connect the source line SL to the ground potential node.

In addition, the row decoder 13 selects the word line WL1, and applies a read voltage VCGR to the selected word line WL1. The read voltage VCGR has a value corresponding to the read level, and is 0 V in, e.g., the threshold value distribution shown in FIG. 4. Furthermore, the row decoder 13 applies a voltage VREAD to the unselected word lines WL0 and WL2 to WL31. The row decoder 13 also applies the voltage VDD to the select gate lines SGD and SGS. The voltage VREAD turns on the memory cell transistor MT regardless of held data. The voltage VDD applied to the select gate lines SGD and SGS is a voltage capable of turning on select transistors ST1 and ST2.

As a result, the memory cell transistors MT connected to the unselected word lines WL0 and WL2 to WL31 are turned on, and channels are formed. The select transistors ST1 and ST2 are also turned on. When the memory cell transistor MT connected to the selected word line WL1 is turned on, the bit line BL and source line SL are electrically connected. That is, current flows from the bit line BL to the source line SL. On the other hand, when the memory cell transistor MT connected to the selected word line WL1 is kept OFF, the bit line BL and source line SL are electrically disconnected. That is, no current flows from the bit line BL to the source line SL. The sense amplifier 12 senses and amplifies this current. The operation described above reads data from all the bit lines at once.

Based on the result sensed and amplified by the sense amplifier 12, the data pattern monitoring circuit 23 counts memory cell transistors MT having passed the verify and/or memory cell transistors MT having failed the verify, i.e., ON cells and/or OFF cells, and outputs the counts to the control signal generator 16. Also, in the period from the precharge of the bit lines BL to the sensing of data, the operational amplifier 32 of the cell source monitoring circuit 21 compares a voltage VSL of the source line SL with the reference voltage VREF_SRC, and outputs the comparison result to the control signal generator 16.

### Operation of Sense Amplifier 12

The operation of the sense amplifier 12 from the precharge to the sensing will be explained below with reference to FIG. 5. In the following explanation, an operation in which the memory cell transistor MT is turned on when data is read will be called binary-1 read, and an operation in which the memory cell transistor MT is kept OFF when data is read will be called binary-0 read. Note that during the verify operation, signals S1 and S2 are respectively at, e.g., (Vt+0.9 V) and (Vt+1.2 V), and signal BLCLAMP is at (VTN+0.7 V). Vt is the threshold voltage of MOS transistors 64 and 66, and VTN is the threshold voltage of MOS transistor 65.

First, the operation of binary-1 read will be explained.

Initially, the bit line BL is precharged. To perform this precharge, the switching element 60 is turned on. Since the memory cell unit 30 is turned on, therefore, current flows through the bit line BL via the switching element 60, the current path of MOS transistor 64, node N1, and the current path of MOS transistor 65. Consequently, the potential of the bit line BL becomes about a precharge potential VPRE (e.g., 0.7 V). That is, the potential of the bit line BL is fixed to VPRE while current flows from the bit line BL to the source line SL. Also, since the switching element 61 is turned on, the capacitive element 68 is charged, so the potential of node N2 becomes about 2.5 V. The switching elements 62 and 63 are kept OFF.

Then, node N2 is discharged. That is, the switching element 61 is turned off. Accordingly, current flowing from node N2 to the bit line BL discharges node N2, so the potential of node N2 decreases to about 0.9 V. When the potential of node N1 starts decreasing from 0.9 V, MOS transistor 64 starts supplying a current. As a consequence, the potential of node N1 is maintained at 0.9 V.

Subsequently, data is sensed. As shown in FIG. 5, the switching element 62 is turned on. Also, MOS transistor 67 is turned on because the potential of node N2 is 0.9 V. Therefore, the latch circuit 69 holds the voltage VDD. Since the latch circuit 69 holds VDD, the switching element 60 is turned off, and the switching element 63 is turned on. Consequently, the potential of node N2 becomes almost 0 V, so the latch circuit 69 stabilizes while holding the voltage VDD (while holding binary 1). Also, current flows from the bit line BL to node N_VSS via the switching element 63, so the potential of the bit line BL becomes almost 0 V.

The operation of binary-0 read will now be explained. In this operation, even when the bit line BL is precharged to VPRE, no current flows through the bit line BL, so the potential of the bit line BL is held almost constant at VPRE. The potential of node N2 maintains about 2.5 V. Accordingly, MOS transistor 67 is turned off, and the latch circuit 69 holds 0 V. Consequently, the switching element 60 is turned on, the switching element 63 is turned off, the potential of node N2 maintains 2.5 V, and the latch circuit 69 stabilizes while holding 0 V (while holding binary 0).

The sense amplifier 12 senses and amplifies the data read to the bit line as described above. In this embodiment, data read (the process from the precharge to the sensing described above) is performed once or more than once (e.g., twice) when verifying the data. When performing data read twice, data is read from the memory cell transistor MT through which the cell current readily flows in the first read, and then data is read from the memory cell transistor MT through which the cell current hardly flows, in order to suppress the influence of noise (fluctuation) of the source line SL. In the second read, data is read while the memory cell transistor MT turned on in the first read is turned off. The number of times of sensing is determined by an instruction from the internal voltage generator 19. This point will be explained below.

### Operation of Control Signal Generator 16

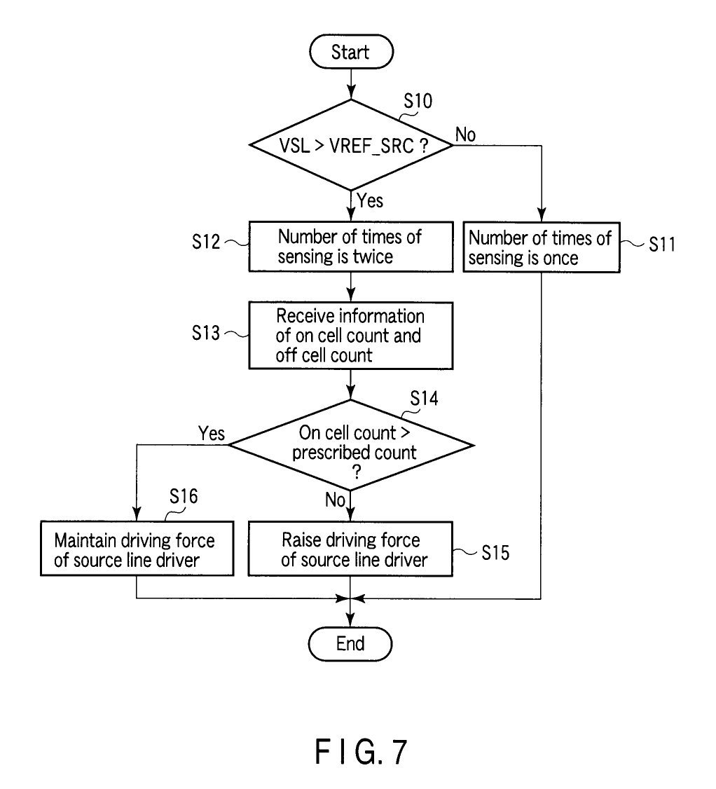

The operation of the control signal generator 16 in the aforementioned verify operation will be explained below. FIG. 7 is a flowchart showing a part of the processing of the control signal generator 16 in the verify operation.

As shown in FIG. 7, during the period from the precharge to the data sensing or at the timing immediately after the sensing, the control signal generator 16 determines whether the voltage VSL of the source line SL has exceeded the reference voltage VREF_SRC (step S10). This determination can be performed by a signal supplied from the cell source monitoring circuit 21. If the voltage VSL has not exceeded the reference voltage VREF_SRC(NO in step S10), the control signal generator 16 determines that the number of times of sensing in this verify is once (step S11), and notifies the sense amplifier 12 and row decoder 13 of this decision. In this case, therefore, the programming operation is repeated with stepping up VPGM or the write operation is terminated without reading data again.

On the other hand, if the voltage VSL has exceeded the reference voltage VREF_SRC (YES in step S10), the control signal generator 16 determines that the number of times of sensing in this verify is greater than one (e.g., twice) (step S12), and notifies the sense amplifier 12 and row decoder 13 of this decision. In this case, therefore, the bit line BL is precharged again, and the voltages VCGR and VREAD are applied to the word line WL, thereby reading data. This is so because the sense amplifier 12 may misguidedly determine that the memory cell transistor MT that is actually ON is OFF because the current flowing through the bit line BL decreases owing to the floating of the voltage VSL.

After the first sensing, the control signal generator 16 receives information of the ON cell count and OFF cell count from the data pattern monitoring circuit (step S13). The control signal generator 16 determines whether the ON cell count has exceeded a prescribed count (step S14).

If the ON cell count has exceeded the prescribed count (YES in step S14), the control signal generator 16 makes the driving force of the source line driver 20 in the second read equal to that in the first read (step S16). That is, the current driving force of MOS transistor 31 remains unchanged.

On the other hand, if the ON cell count has not exceeded the prescribed count (NO in step S14), i.e., if the ON cell count is less than or equal to the prescribed count, the control signal generator 16 makes the driving force of the source line driver 20 in the second read greater than that in the first read (step S15). That is, the current driving force of MOS transistor 31 rises.

As described above, the control signal generator 16 determines whether to set the number of times of reading to once or more than once, and controls the driving force of the source line driver 20 from the second read.

### Changes in Voltages at Nodes in Verify Operation

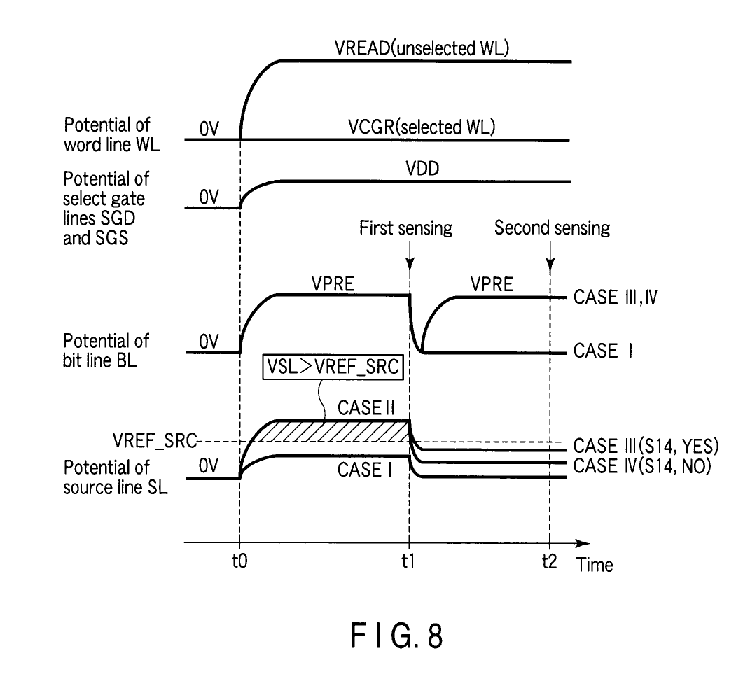

The potentials of the word line WL, select gate lines SGD and SGS, bit line BL, and source line SL in the above-mentioned verify operation will be explained below with reference to FIG. 8. FIG. 8 is a timing chart of these potentials.

After the programming operation, the verify operation starts at time t0. At time t0 as shown in FIG. 8, the row decoder 13 applies the voltage VCGR (=0 V) to a selected word line WL, and the voltage VREAD to an unselected word line WL. The row decoder 13 also applies the voltage VDD to the select gate lines SGD and SGS. The sense amplifier 12 precharges the bit line BL to the voltage VPRE. In addition, the source line driver 20 and row decoder 13 respectively apply 0 V to the source line SL and well region 42. Note that these voltages need not be applied at the same time and can also be applied at different timings.

As a consequence, the cell current flows from the bit line BL to the source line SL, and the first data read is performed. During the period of the first read, the driving force of the source line driver 20 is constant, so the voltage VSL of the source line SL fluctuates in accordance with the magnitude of the cell current.

In CASE I of FIG. 8, the voltage VSL has not exceeded the reference voltage VREF_SRC. In this case, the control signal generator 16 determines that the number of times of sensing is once. At time t1, sensing is performed, and the verify operation is terminated. After that, the programming operation is repeated as needed, or the write operation is terminated.

In CASE II of FIG. 8, the voltage VSL has exceeded the reference voltage VREF_SRC in the first read. In this case, the control signal generator 16 determines that the number of times of sensing is greater than one (e.g., twice). After the first sensing is performed at time t1, the second read is performed.

That is, in response to an instruction from the control signal generator 16, the sense amplifier 12 precharges the bit line BL again, which is connected to the memory cell transistor MT found to be OFF in the first read. The bit line BL connected to the memory cell transistor MT found to be ON is fixed at a predetermined potential, e.g., 0 V. Also, in accordance with information of the ON cell count and OFF cell count in the first read, the control signal generator 16 controls the driving force of the source line driver 20 in the second read. In the following description, the ON cell count has exceeded a prescribed count (YES in step S14) in CASE III, and has not exceeded the prescribed count (NO in step S14) in CASE IV.

In CASE III, the driving force of the source line driver 20 is the same as that in the first read. Since, however, the number of the bit lines BL through which current flows is smaller than that in the first read, the rise in voltage VSL of the source line SL is suppressed. On the other hand, in CASE IV, the driving force of the source line driver 20 is set greater than that in the first read. Accordingly, the rise in voltage VSL is suppressed. Note that in FIG. 8, VSL in CASE III is higher than that in CASE IV for the sake of convenience in order to visually clearly show that there are two cases. In some cases, therefore, VSL in CASE IV can be higher than that in CASE III, or the two VSLs can also be the same.

At time t2, the sense amplifier 12 performs the second sensing, and terminates the verify operation. After that, the programming operation is performed again, or the write operation is terminated.

### <Read Operation>

The data read operation is the same as the aforementioned verify operation.

### <Effect>

As described above, the NAND flash memory according to the first embodiment of the present invention achieves the effect of item (1) below.

(1) The operating performance of the NAND flash memory can be improved.

The NAND flash memory according to this embodiment includes the cell source monitoring circuit 21 for monitoring the voltage of the source line SL in the data read operation and verify operation, and the data pattern monitoring circuit 23 for counting ON cells and OFF cells in these operations. The number of times of data read (the number of times of sensing) is determined in accordance with the monitoring result in the cell source monitoring circuit 21. When the number of times of reading is greater than one, the performance of the source line driver 20 from the second read is determined in accordance with the counts of the data pattern monitoring circuit 23. Accordingly, the operating performance of the NAND flash memory can be improved. Details of this effect will be explained below.

A method of simultaneously reading data from all bit lines by sensing current is conventionally known. In this method, the bit lines must be held at a predetermined potential during the read period in order to eliminate the influence of noise of adjacent bit lines. During the read period, therefore, current is kept supplied to the bit lines. Consequently, the total cell current becomes very large, i.e., about 100 mA. Since the cell current flows into a source line, the potential of the source line also rises.

Accordingly, sensing must be performed more than once in order to prevent a data read error. That is, memory cell transistors with larger cell currents are sequentially excluded in order of decreasing cell current. Finally, the results of a sensing operation performed with the rise in the potential of the source line inhibited are loaded into a latch circuit. On the other hand, the total cell current is sometimes small depending on a data pattern. In this case, sensing need not be performed more than once because there is almost no rise in source line potential and a read error hardly occurs.

It is, however, necessary to perform the read operation by assuming a worst data pattern. Therefore, sensing must always be performed more than once regardless of a data pattern. That is, the second read is performed even when the cell current flowing in the first read is small and a read error hardly occurs. Consequently, read is needlessly performed more than once in some cases, and this decreases the operating speed of the NAND flash memory.

In the NAND flash memory according to this embodiment, however, the cell source monitoring circuit 21 monitors whether the voltage VSL of the source line SL has exceeded the reference voltage VREF_SRC. If the voltage VSL has exceeded the reference voltage VREF_SRC, read is performed more than once (e.g., twice, but this is not limited to twice). If the voltage VSL has not exceeded the reference voltage VREF_SRC, read is performed once. That is, the number of times of sensing is greater than one when the cell current is large, and once when the cell current is small. This makes it possible to perform data read more than once only when necessary, and perform data read only once when unnecessary. Accordingly, the operating speed of the NAND flash memory can be increased.

Furthermore, in the NAND flash memory according to this embodiment, the data pattern monitoring circuit 23 monitors the verify result. If the ON cell count has not exceeded the prescribed count, the performance of the source line driver 20 in the second read is raised. This is so because the ON cell count presumably increases in the second sensing when the ON cell count is small in the first sensing. Therefore, the rise in voltage VSL of the source line SL can be suppressed by raising the performance of the source line driver 20, thereby preventing a read error in the second read. On the other hand, if the ON cell count is large in the first sensing, current that flows through the bit line BL in the second sensing is probably small. This is so because the bit line BL connected to the memory cell transistors MT is fixed to 0 V in the second read. Accordingly, even when the performance of the source line driver 20 remains the same, the rise in voltage VSL of the source line SL is small, and the read error occurrence probability is low.

As described above, the write operation speed can be increased by increasing the data read speed. In addition, the operating performance of the NAND flash memory can be increased because read errors can be suppressed.

### Second Embodiment

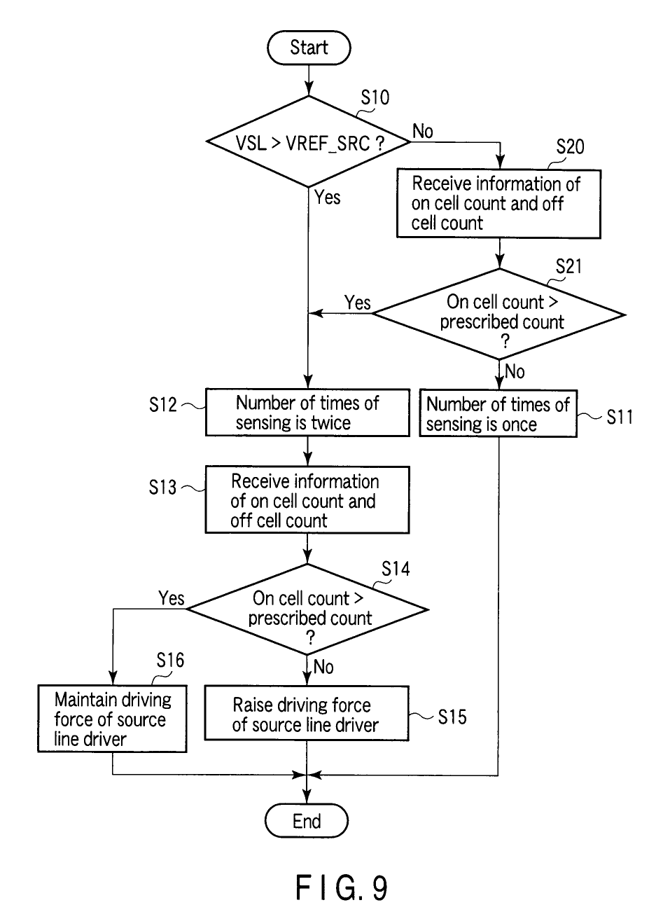

A semiconductor memory device according to the second embodiment of the present invention will be explained below. In this embodiment, the number of times of data read is determined based not only on a voltage VSL but also on the monitoring result in a data pattern monitoring circuit 23 in the data read operation and verify operation of the first embodiment. Only the difference from the first embodiment will be explained below. FIG. 9 is a flowchart showing a part of the processing of a control signal generator 16 in the read operation and verify operation.

In step S10 as shown in FIG. 9, the control signal generator 16 determines whether the voltage VSL of a source line SL has exceeded a reference voltage VREF_SRC. If the voltage VSL has exceeded the reference voltage VREF_SRC (YES in step S10), the control signal generator 16 determines that the number of times of reading is twice (step S12). This is the same as in the first embodiment.

On the other hand, if the voltage VSL has not exceeded the reference voltage VREF_SRC (NO in step S10), the control signal generator 16 receives information of the ON cell count and OFF cell count from the data pattern monitoring circuit 23 (step S20). The control signal generator 16 determines whether the ON cell count has exceeded a prescribed count (step S21). This prescribed count used in step S21 can be the same as or different from a prescribed count used in step S14. If the ON cell count has not exceeded the prescribed count (NO in step S21), the control signal generator 16 determines that the number of times of reading is once (step S11). However, if the ON cell count has exceeded the prescribed count (YES in step S21), the control signal generator 16 determines that the number of times of reading is twice (step S12). The rest of the operation is the same as that of the first embodiment, so a repetitive explanation will be omitted.

### <Effect>

As described above, the NAND flash memory according to the second embodiment of the present invention achieves the effect of item (2) below in addition to the effect of item (1) explained in the first embodiment.

(2) The operating reliability of the NAND flash memory can be improved.

In the NAND flash memory according to this embodiment, the number of times of reading is determined based on both the voltage VSL and ON cell count. Accordingly, it is possible to more effectively prevent the occurrence of a read error, and improve the operating reliability of the NAND flash memory. This effect will be explained below.

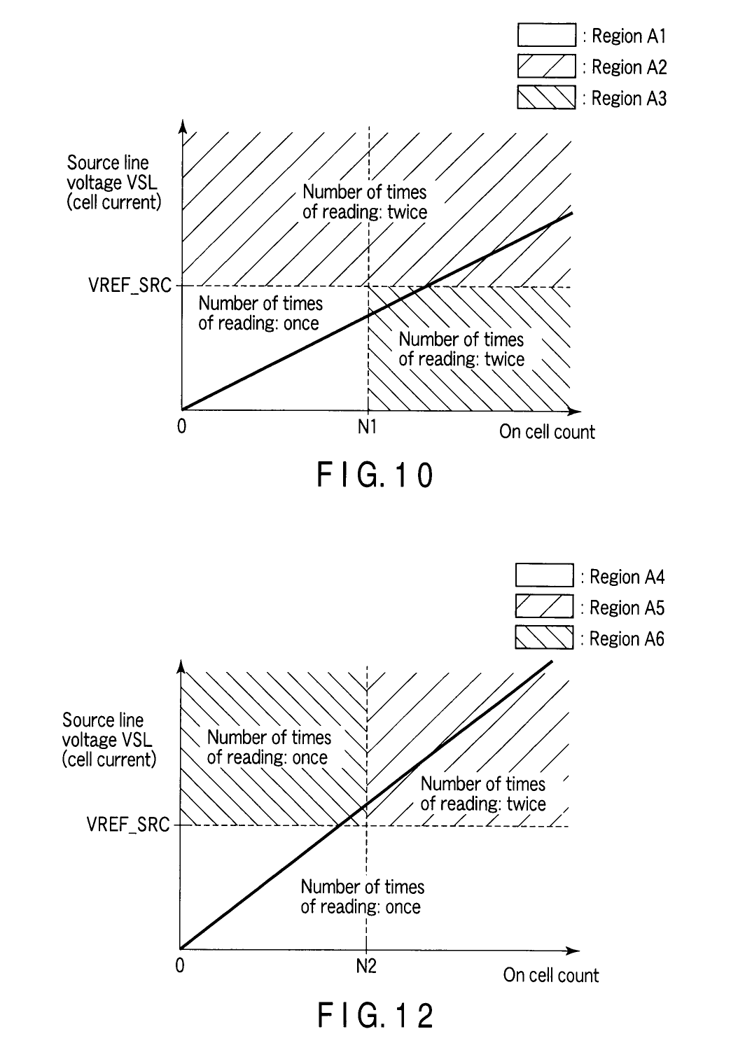

FIG. 10 is a graph showing the relationship between the number of ON cells contained in one page and the voltage VSL (i.e., the cell current) in the read operation and verify operation. Although the voltage VSL is proportional to the ON cell count in FIG. 10, they need not always have the proportional relationship. Generally, however, the voltage VSL increases as the ON cell count increases. Also, the increase in voltage VSL varies depending on, e.g., the characteristics of a memory cell transistor MT. The graph of FIG. 10 shows an example.

As shown in FIG. 10, when the voltage VSL has exceeded the reference voltage VREF_SRC, read is performed twice regardless of the ON cell count. This corresponds to a hatched region A2 in FIG. 10, and is the same as in the first embodiment. In this embodiment, even when the voltage VSL has not exceeded the reference voltage VREF_SRC, read is performed twice if the ON cell count has exceeded a predetermined prescribed count N1. This corresponds to a hatched region A3 in FIG. 10. Read is performed only once when the voltage VSL has not exceeded the reference voltage VREF_SRC, and the ON cell count has not exceeded the prescribed count N1. This corresponds to a hollow region A1 in FIG. 10.

In the region A3, the voltage VSL is less than or equal to the reference voltage VREF_SRC although the ON cell count is large. When the ON cell count is large, it is highly likely that the voltage VSL is lower than the reference voltage VREF_SRC but has risen to a level close to the reference voltage VREF_SRC. That is, the difference between the voltage VSL and the reference voltage VREF_SRC may be very small. Therefore, read is performed twice in this case.

As described above, this embodiment can finely set the number of times of reading case by case, and improve the operating reliability of the NAND flash memory.

### Third Embodiment

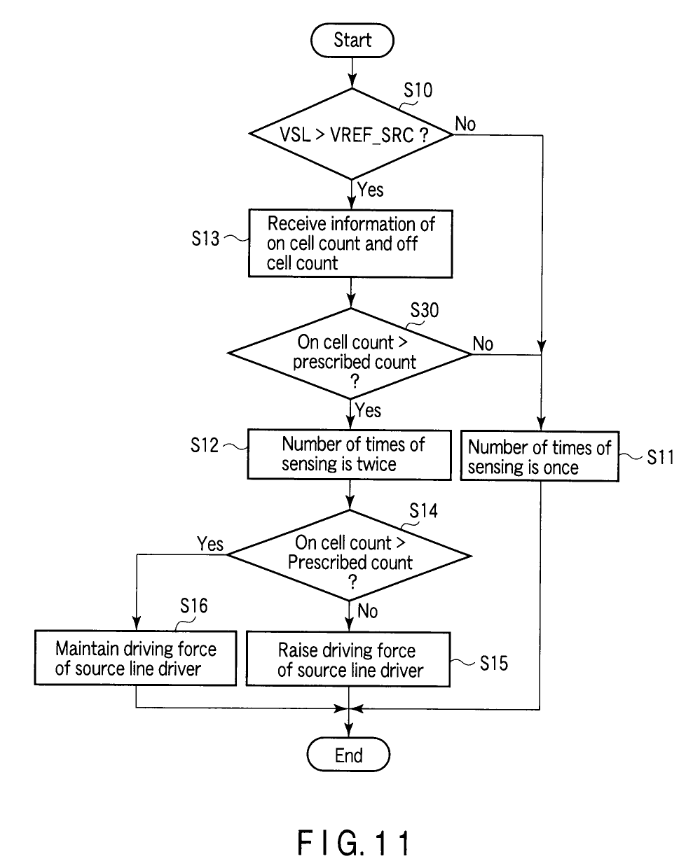

A semiconductor memory device according to the third embodiment of the present invention will be explained below. This embodiment is the same as the above-mentioned second embodiment in that the number of times of reading in the data read operation and data verify operation is determined based not only on a voltage VSL but also on the monitoring result in a data pattern monitoring circuit 23. Only the difference from the first embodiment will be explained below. FIG. 11 is a flowchart showing a part of the processing of a control signal generator 16 in the verify operation.

In step S10 as shown in FIG. 11, the control signal generator 16 determines whether the voltage VSL of a source line SL has exceeded a reference voltage VREF_SRC. If the voltage VSL has not exceeded the reference voltage VREF_SRC (NO in step S10), the control signal generator 16 determines that the number of times of reading is once (step S11). This is the same as in the first embodiment.

On the other hand, if the voltage VSL has exceeded the reference voltage VREF_SRC (YES in step S10), the control signal generator 16 receives information of the ON cell count and OFF cell count from the data pattern monitoring circuit 23 (step S13). The control signal generator 16 determines whether the ON cell count has exceeded a prescribed count (step S30). This prescribed count used in step S30 can be the same as or different from a prescribed count used in step S14. If the ON cell count has not exceeded the prescribed count (NO in step S30), the control signal generator 16 determines that the number of times of reading is once (step S11). However, if the ON cell count has exceeded the prescribed count (YES in step S30), the control signal generator 16 determines that the number of times of reading is twice (step S12). The rest of the operation is the same as that of the first embodiment, so a repetitive explanation will be omitted.

### <Effect>

As described above, the NAND flash memory according to the third embodiment of the present invention achieves the effect of item (3) below in addition to the effect of item (1) explained in the first embodiment.

(3) The operating speed of the NAND flash memory can be increased.

FIG. 12 is a graph showing the relationship between the number of ON cells contained in one page and the voltage VSL in the read operation and verify operation. As shown in FIG. 12, when the voltage VSL has not exceeded the reference voltage VREF_SRC, the number of times of reading is once regardless of the ON cell count. This corresponds to a hollow region A4 in FIG. 12, and is the same as in the first embodiment.

In this embodiment, even when the voltage VSL has exceeded the reference voltage VREF_SRC, the number of times of reading is once if the ON cell count has not exceeded a predetermined prescribed count N2. This corresponds to a hatched region A6 in FIG. 12. Read is performed twice when the voltage VSL has exceeded the reference voltage VREF_SRC, and the ON cell count has exceeded the prescribed count N2. This corresponds to a hatched region A5 in FIG. 12.

In the region A6, the ON cell count is small although the voltage VSL has exceeded the reference voltage VREF_SRC. When the ON cell count is small, it is highly likely that the voltage VSL has a value close to the reference voltage VREF_SRC even if the voltage VSL has exceeded the reference voltage VREF_SRC. That is, the difference between the voltage VSL and the reference voltage VREF_SRC may be very small. Accordingly, read is performed once in this case.

From the foregoing, it is possible to perform read more than once only when necessary, and increase the operating speed of the NAND flash memory.

### Fourth Embodiment

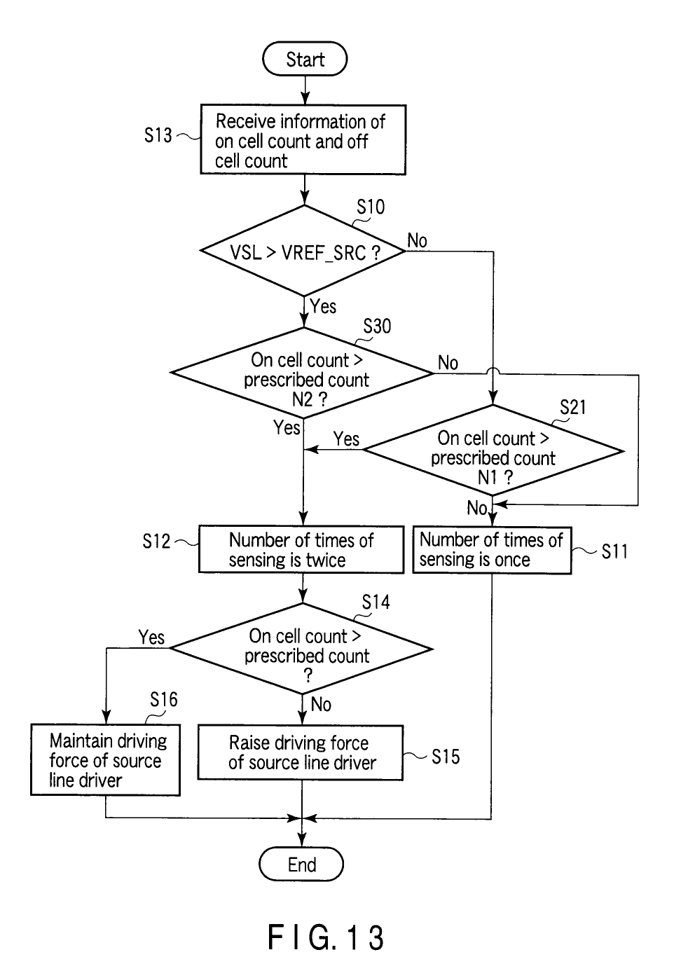

A semiconductor memory device according to the fourth embodiment of the present invention will be explained below. This embodiment is a combination of the second and third embodiments described above. FIG. 13 is a flowchart showing a part of the processing of a control signal generator 16 in the read operation and verify operation.

As shown in FIG. 13, the control signal generator 16 first receives information of the ON cell count and OFF cell count from a data pattern monitoring circuit 23 (step S13). If a voltage VSL has exceeded a reference voltage VREF_SRC (YES in step S10), the control signal generator 16 determines whether the ON cell count has exceeded a prescribed count (step S30). Assume that the prescribed count used in this step is a prescribed count N2. The prescribed count N2 can, of course, be the same as or different from a prescribed count used in step S14. If the ON cell count has not exceeded the prescribed count N2 (NO in step S30), the control signal generator 16 determines that the number of times of reading is once (step S11). However, if the ON cell count has exceeded the prescribed count N2 (YES in step S30), the control signal generator 16 determines that the number of times of reading is twice (step S12).

On the other hand, if the voltage VSL has not exceeded the reference voltage VREF_SRC in step S10 (NO in step S10), the control signal generator 16 determines whether the ON cell count has exceeded a prescribed count (step S21). Assuming that the prescribed count used in this step is a prescribed count N1, N2<N1 holds. The prescribed count N1 can, of course, be the same as or different from the prescribed count used in step S14, provided that, for example, the prescribed count N2<the prescribed count used in step S14<the prescribed count N1 holds. If the ON cell count has not exceeded the prescribed count N1 (NO in step S21), the control signal generator 16 determines that the number of times of reading is once (step S11). However, if the ON cell count has exceeded the prescribed count N1 (YES in step S21), the control signal generator 16 determines that the number of times of reading is twice (step S12).

### <Effects>

As described above, the NAND flash memory according to the fourth embodiment of the present invention achieves the effects of items (1) to (3) explained in the first to third embodiments.

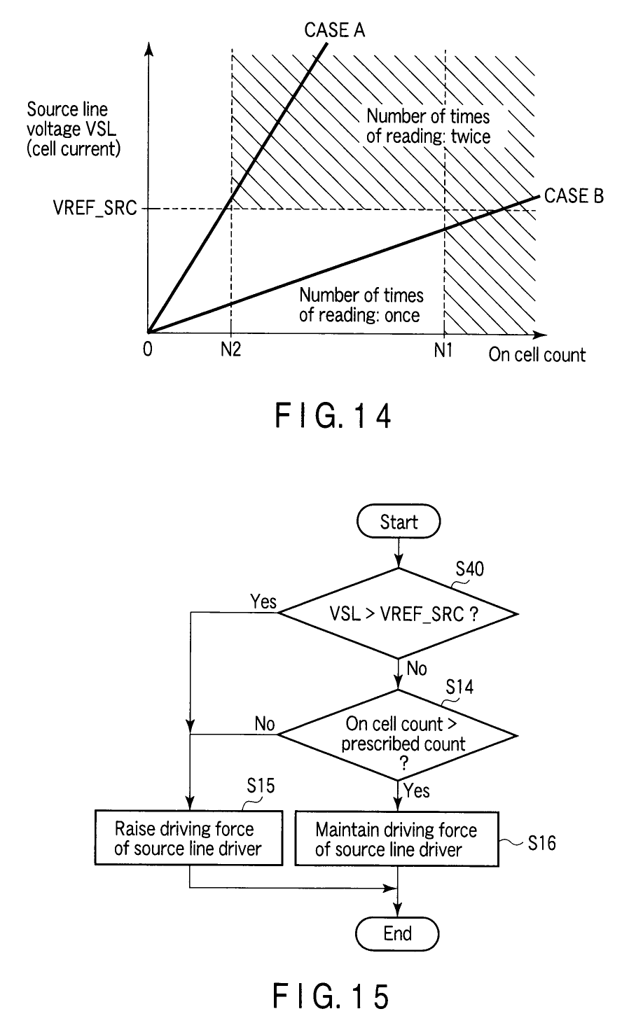

FIG. 14 is a graph showing the relationship between the number of ON cells contained in one page and the voltage VSL in the NAND flash memory according to this embodiment. FIG. 14 shows two cases, i.e., CASE A and CASE B. Referring to FIG. 14, the number of times of reading is twice in a hatched region, and once in a hollow region.

In the method according to this embodiment as shown in FIG. 14, even when the voltage VSL is less than or equal to the reference voltage VREF_SRC, read is performed twice if the ON cell count is large. On the other hand, even when the voltage VSL has exceeded the reference voltage VREF_SRC, read is performed only once if the ON cell count is small. This makes it possible to achieve a high speed and high reliability of the NAND flash memory at the same time.

### Fifth Embodiment

A semiconductor memory device according to the fifth embodiment of the present invention will be explained below. In this embodiment, the performance of a source line driver 20 in the data read operation and data verify operation is determined based not only on the monitoring result in a data pattern monitoring circuit 23, but also on the detection result of a voltage VSL in a cell source monitoring circuit 21, in any of the first to fourth embodiments described above. Only the difference from the first to fourth embodiments will be explained below. FIG. 15 is a flowchart showing a part of the processing of a control signal generator 16 in the read operation and verify operation, and corresponds to the processes in steps S14 to S16 of FIGS. 7, 9, 11, and 13.

As shown in FIG. 15, based on the detection result in the cell source monitoring circuit 21, the control signal generator 16 determines whether the voltage VSL of a source line SL has exceeded a reference voltage VREF_SRC (step S40). If the voltage VSL has exceeded the reference voltage VREF_SRC (YES in step S40), the control signal generator 16 raises the driving power of the source line driver 20 in the second read (step S15).

On the other hand, if the voltage VSL has not exceeded the reference voltage VREF_SRC (NO in step S40), the process advances to step S14, and the control signal generator 16 performs the same processing as in the first to fourth embodiments. The rest of the operation is the same as that of the first to fourth embodiments, so a repetitive explanation will be omitted.

### <Effect>

As described above, the NAND flash memory according to the fifth embodiment of the present invention further achieves the effect of item (4) below.

(4) The operating reliability of the NAND flash memory can be improved.

In the NAND flash memory according to this embodiment, the driving force of the source line driver 20 in the second data read is determined based on both the voltage VSL and ON cell count. Accordingly, it is possible to more effectively prevent the occurrence of a read error, and improve the operating reliability of the NAND flash memory.

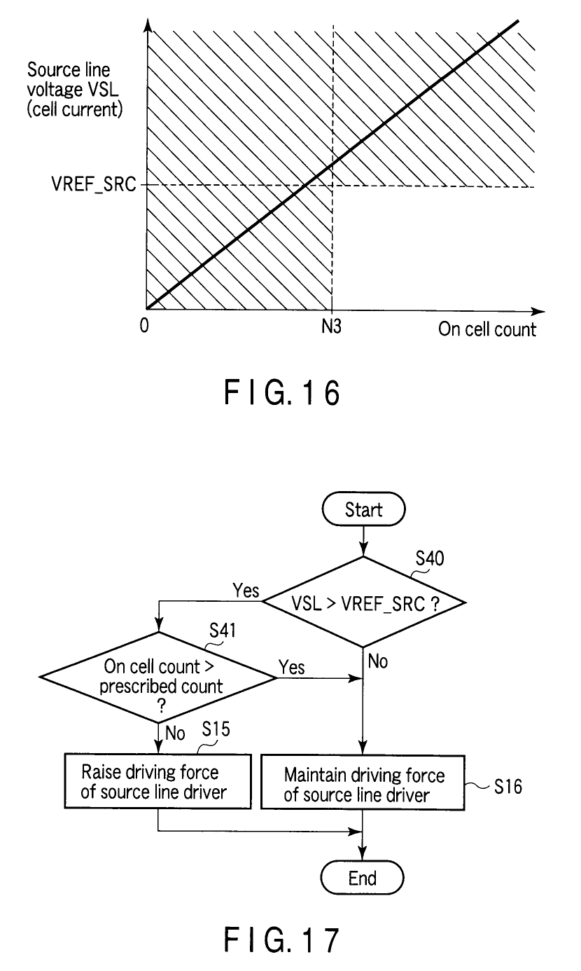

FIG. 16 is a graph showing the relationship between the number of ON cells contained in one page and the voltage VSL, similar to FIGS. 10, 12, and 14. In a hatched region shown in FIG. 16, the driving force of the source line driver 20 is raised in the second read. That is, when the voltage VSL has exceeded the reference voltage VREF_SRC, the driving force of the source line driver 20 is raised regardless of the ON cell count. Also, in this embodiment, even when the voltage VSL has not exceeded the reference voltage VREF_SRC, the driving force of the source line driver 20 is raised if the ON cell count has not exceeded a predetermined prescribed count N3. This is so because, as explained in the first embodiment, there is the possibility that current flowing through a bit line BL is large in the second read. This makes it possible to increase the read accuracy in the second read.

### Sixth Embodiment

A semiconductor memory device according to the sixth embodiment of the present invention will be explained below. This embodiment is the same as the fifth embodiment in that the performance of a source line driver 20 in the data read operation and data verify operation is determined based not only on the monitoring result in a data pattern monitoring circuit 23, but also on the detection result of a voltage VSL in a cell source monitoring circuit 21, in any of the first to fourth embodiments described above. Only the difference from the first to fourth embodiments will be explained below. FIG. 17 is a flowchart showing a part of the processing of a control signal generator 16 in the read operation and verify operation, and corresponds to the processes in steps S14 to S16 of FIGS. 7, 9, 11, and 13.

As shown in FIG. 17, based on the detection result in the cell source monitoring circuit 21, the control signal generator 16 determines whether the voltage VSL of a source line SL has exceeded a reference voltage VREF_SRC (step S40). If the voltage VSL has not exceeded the reference voltage VREF_SRC (NO in step S40), the control signal generator 16 maintains the driving force of the source line driver 20 (step S16). That is, the driving force of the source line driver 20 in the second read is made equal to that in the first read.

On the other hand, if the voltage VSL has exceeded the reference voltage VREF_SRC (YES in step S40), the control signal generator 16 determines whether the ON cell count has exceeded a prescribed count (step S41). If the ON cell count has not exceeded the prescribed count (NO in step S41), the control signal generator 16 raises the driving force of the source line driver 20 (step S15). If the ON cell count has exceeded the prescribed count (YES in step S41), the process advances to step S16. The rest of the operation is the same as that of the first to fourth embodiments, so a repetitive explanation will be omitted.

### <Effect>

The NAND flash memory according to the sixth embodiment of the present invention achieves the effect of item (5) below.

(5) The power consumption of the NAND flash memory can be reduced.

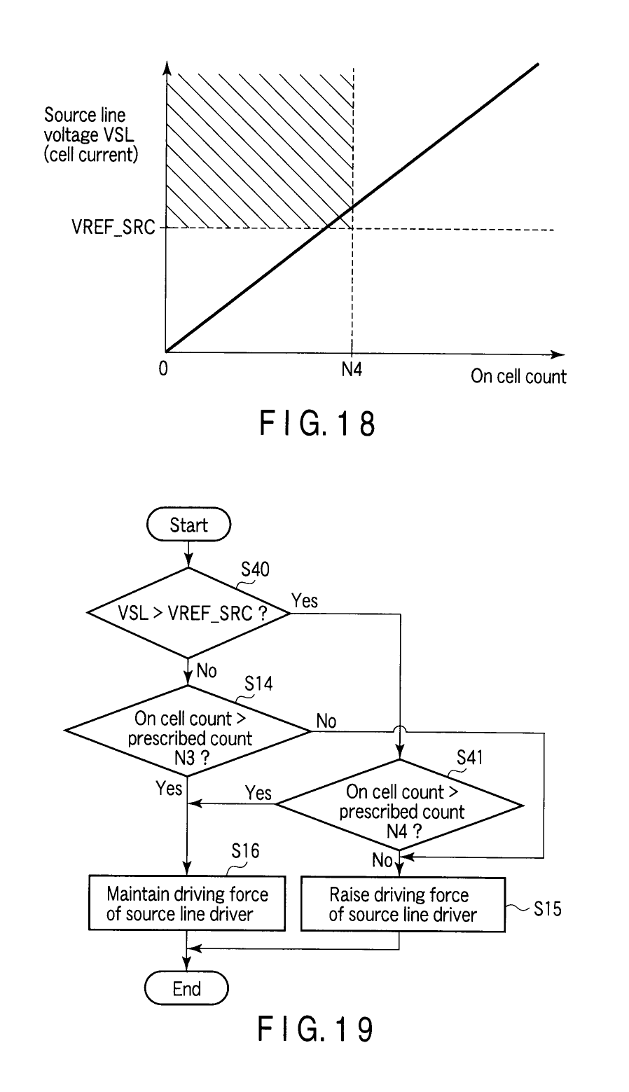

FIG. 18 is a graph showing the relationship between the number of ON cells contained in one page and the voltage VSL, similar to FIG. 16. Referring to FIG. 18, the driving force of the source line driver 20 is raised in a hatched region. That is, when the voltage VSL has not exceeded the reference voltage VREF_SRC, the driving force of the source line driver 20 is held constant regardless of the ON cell count. Also, in this embodiment, even when the voltage VSL has exceeded the reference voltage VREF_SRC, the driving force of the source line driver 20 is held constant if the ON cell count has exceeded a predetermined prescribed count N4. This is so because, as explained in the first embodiment, current flowing through a bit line BL is presumably small in the second read. Accordingly, the driving force of the source line driver 20 need not unnecessarily be raised, so the power consumption of the NAND flash memory can be reduced.

### Seventh Embodiment

A semiconductor memory device according to the seventh embodiment of the present invention will be explained below. This embodiment is a combination of the fifth and sixth embodiments described above. FIG. 19 is a flowchart showing a part of the processing of a control signal generator 16 in the read operation and verify operation, and corresponds to the processes in steps S14 to S16 of FIGS. 7, 9, 11, and 13.

As shown in FIG. 19, if a voltage VSL has not exceeded a reference voltage VREF_SRC (NO in step S40), the control signal generator 16 determines whether the ON cell count has exceeded a prescribed count (step S14). Assume that the prescribed count used in this step is a prescribed count N3. If the ON cell count has exceeded the prescribed count N3 (YES in step S14), the control signal generator 16 holds the driving force of a source line driver 20 constant (step S16). However, if the ON cell count has not exceeded the prescribed count N3 (NO in step S14), the control signal generator 16 raises the driving force (step S15).

On the other hand, if the voltage VSL has exceeded the reference voltage VREF_SRC in step S40 (YES in step S40), the control signal generator 16 determines whether the ON cell count has exceeded a prescribed count (step S41). Assuming that the prescribed count used in this step is N4, N3<N4 holds. If the ON cell count has not exceeded the prescribed count N4 (NO in step S41), the control signal generator 16 raises the driving force (step S15). However, if the ON cell count has exceeded the prescribed count N4 (YES in step S41), the control signal generator 16 maintains the driving force (step S16).

### <Effects>

As described above, the NAND flash memory according to the seventh embodiment of the present invention further achieves the effects of items (4) and (5) explained in the fifth and sixth embodiments.

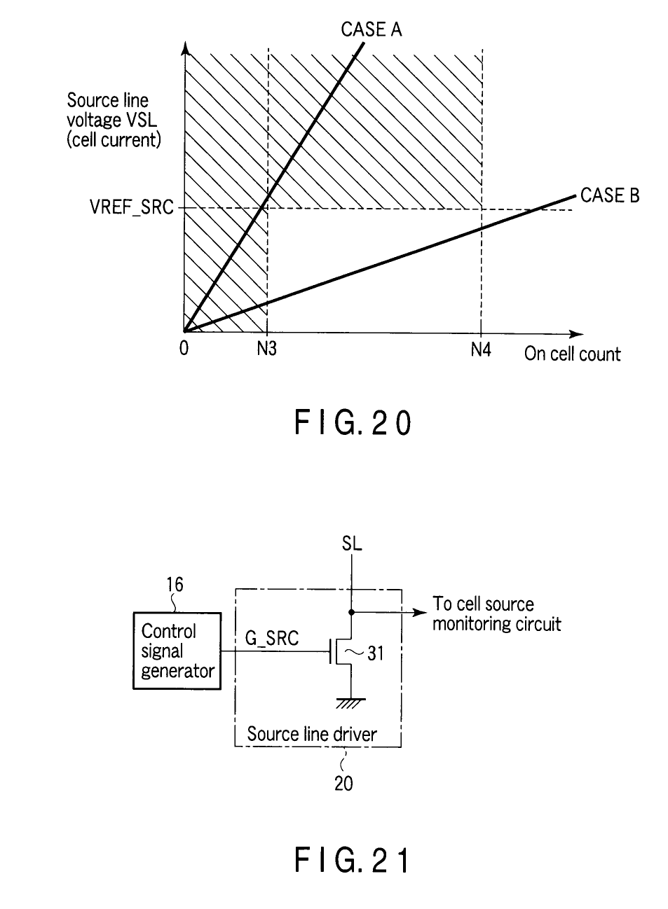

FIG. 20 is a graph showing the relationship between the number of ON cells contained in one page and the voltage VSL in the NAND flash memory according to this embodiment. FIG. 20 shows two cases, i.e., CASE A and CASE B. Referring to FIG. 20, the driving force of the source line driver 20 is raised in a hatched region.

As shown in FIG. 20, even when the voltage VSL is less than or equal to the reference voltage VREF_SRC, the method according to this embodiment raises the performance of the source line driver 20 if the ON cell count is small. On the other hand, even when the voltage VSL has exceeded the reference voltage VREF_SRC, the method maintains the performance of the source line driver 20 if the ON cell count is large. This makes it possible to achieve high reliability and low power consumption of the NAND flash memory at the same time.

### Eighth Embodiment

A semiconductor memory device according to the eighth embodiment of the present invention will be explained below. This embodiment is directed to the arrangement of a source line driver 20 in the first to seventh embodiments described above, and a method of controlling the source line driver 20 by a control signal generator 16. The configuration except for the arrangement of the source line driver 20 is the same as that of the first to seventh embodiments, so a repetitive explanation will be omitted.

### First Example

FIG. 21 is a block diagram of a source line driver 20 and control signal generator 16 according to the first example. As shown in FIG. 21, the control signal generator 16 controls the potential of a signal G_SRC input to the gate of a MOS transistor 31.

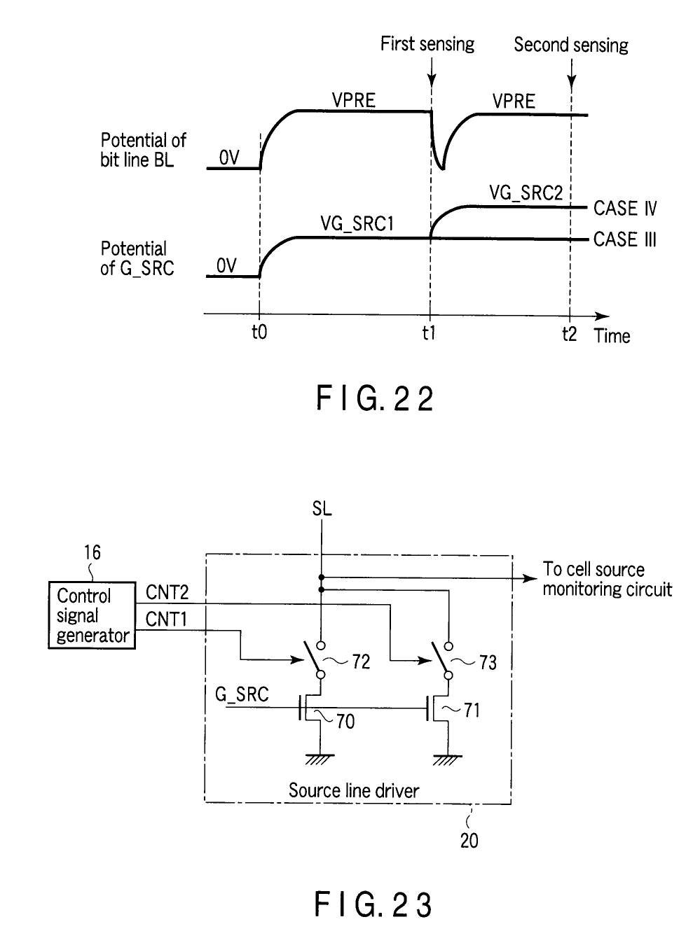

FIG. 22 is a timing chart showing the potentials of a bit line BL and signal G_SRC in data read and verify. Times t0 to t2 on the abscissa of FIG. 22 correspond to FIG. 8. In the first read period as shown in FIG. 22, the control signal generator 16 sets the potential of signal G_SRC at VG_SRC1. In the second read period, the control signal generator 16 maintains signal G_SRC at VG_SRC1 if the ON cell count has not exceeded a prescribed count (NO in step S14, CASE III). On the other hand, if the ON cell count has exceeded the prescribed count (YES in step S14, CASE IV), the control signal generator 16 sets signal G_SRC at VG_SRC2 (>VG_SRC1), thereby increasing the current driving force of MOS transistor 31.

### Second Example

FIG. 23 is a block diagram of a source line driver 20 and control signal generator 16 according to the second example. As shown in FIG. 23, the source line driver 20 includes two MOS transistors 70 and 71, instead of MOS transistor 31, and further includes switching elements 72 and 73. MOS transistors 70 and 71 have the gates to which a signal G_SRC is supplied, the sources that are grounded, and the drains respectively connected to a source line SL via the switching elements 72 and 73. The control signal generator 16 generates signals CNT1 and CNT2, thereby controlling the switching elements 72 and 73.

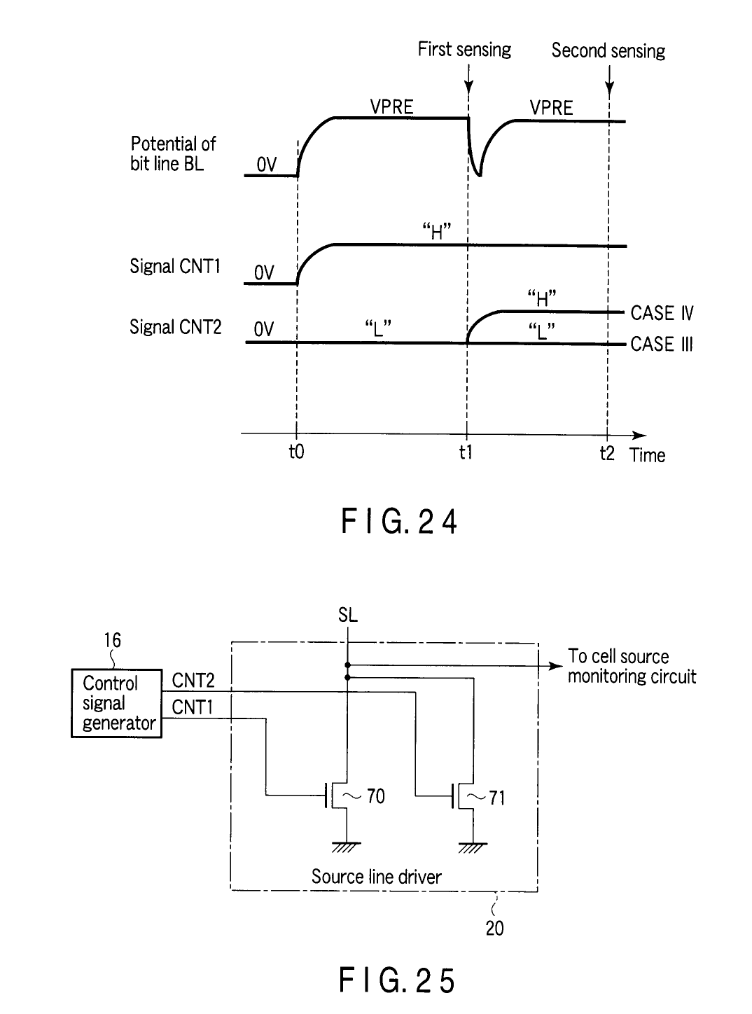

FIG. 24 is a timing chart showing the potentials of a bit line BL and signals CNT1 and CNT2 in data read and verify. Times t0 to t2 on the abscissa of FIG. 24 correspond to FIG. 8. In the first read period as shown in FIG. 24, the control signal generator 16 makes signals CNT1 and CNT2 respectively high and low. Consequently, MOS transistor 70 is connected to the source line SL, and MOS transistor 71 is disconnected. In the second read period, if the ON cell count has not exceeded a prescribed count (NO in step S14, CASE III), the control signal generator 16 respectively keeps signals CNT1 and CNT2 high and low. On the other hand, if the ON cell count has exceeded the prescribed count (YES in step S14, CASE IV), the control signal generator 16 makes not only signal CNT1 but also signal CNT2 high, thereby connecting MOS transistor 71 to the source line SL. Consequently, the two MOS transistors 70 and 71 ground the source line SL, thereby increasing the performance of the source line driver 20.

### Third Example

FIG. 25 is a block diagram of a source line driver 20 and control signal generator 16 according to the third example. As shown in FIG. 25, the source line driver 20 includes two MOS transistors 70 and 71, instead of MOS transistor 31. MOS transistors 70 and 71 have the sources that are grounded, the drains connected to a source line SL, and the gates to which signals CNT1 and CNT2 are input. The control signal generator 16 generates signals CNT1 and CNT2, thereby controlling ON/OFF of MOS transistors 70 and 71.

The potentials of a bit line BL and signals CNT1 and CNT2 in data read and verify are the same as those shown in FIG. 24. That is, in CASE IV, the performance of the source line driver 20 is increased by turning on both MOS transistors 70 and 71.

As described above, the driving force of the source line driver 20 can be controlled by the gate potential of MOS transistor 31, or the number of MOS transistors capable of discharging the potential of the source line to ground, among the plurality of MOS transistors described above. However, the arrangement of the source line driver 20 is not limited to the above arrangement, provided that the control signal generator 16 can vary the performance of the source line driver 20.

As described above, the NAND flash memories according to the first to eighth embodiments of the present invention each include the counter 23 which counts ON memory cells MT and/or OFF memory cells MT in the read operation and verify operation, and the detector 21 which detects whether the voltage VSL of the source line SL has exceeded the reference voltage VREF_SRC in the read operation and verify operation. The controller 16 controls the number of times of data sensing in the sense amplifier 12 in accordance with the detection result in the detector 21, or the detection result in the detector 21 and the count in the counter 23. In addition, the controller 16 controls the driving force of the source line driver 20 based on the count in the counter 23, or the count and the detection result in the detector 21. This makes it possible to improve the operating reliability of the NAND flash memory.

Note that the above embodiments have been explained by taking, for example, the arrangement in which the cell source monitoring circuit 21 detects the voltage VSL of the source line SL. However, current may also be detected instead of the voltage. For example, it is also possible to equip the cell source monitoring circuit 21 with a MOS transistor that forms a current mirror circuit together with MOS transistor 31, compare current flowing through this MOS transistor with a reference current, and supply the comparison result to the control signal generator 16. Note also that the source of MOS transistor 31 need not always be grounded and may also receive a certain predetermined potential. This potential is, e.g., a positive potential. In this case, a voltage obtained by adding this positive potential to the read level is applied to the word line when reading data.

The cell source monitoring circuit 21 need only monitor the voltage of the source line SL in only the first read, and need not always monitor the voltage from the second read. This similarly applies to the data pattern monitoring circuit 23.

The control signal generator 16 may also control the number of times of sensing and the performance of the source line driver 20 in only one of the verify operation and read operation, or in both of them. It is, of course, also possible to perform the same control in an erase verify operation performed after data is erased.

Furthermore, the above embodiments have been explained by taking, for example, the arrangement in which the charge accumulation layer 44 of the memory cell transistor MT is made of a conductor (e.g., a polysilicon layer). However, the charge accumulation layer 44 may also be made of an insulator such as a silicon nitride film. That is, a so-called MONOS structure may also be formed. In addition, the memory cell transistor MT may also be made able to hold data having two bits or more. When using the memory cell transistor MT capable of holding, e.g., two-bit data, the threshold value distribution of the memory cell transistor MT can take four states. When reading data, voltages (read levels) between these states are sequentially generated as the voltage VCGR.

Moreover, the above embodiments have been explained by taking a NAND flash memory as an example. However, the embodiments are applicable to, e.g., a NOR flash memory, and applicable to all semiconductor memory devices having the problem that the increase in cell current raises the source line potential.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a memory cell including a charge accumulation layer and a control gate, and configured to hold data;
a bit line electrically connected to a drain of the memory cell;
a source line electrically connected to a source of the memory cell;
a source line driver which applies a voltage to the source line;
a sense amplifier which reads the data by sensing current flowing through the bit line in a read operation and/or a verify operation of the data;
a counter which counts ON memory cells and/or OFF memory cells in the read operation and/or the verify operation;
a detector which detects whether the voltage of the source line has exceeded a reference voltage, in the read operation and/or the verify operation; and
a controller which controls the number of times of data sensing by the sense amplifier in accordance with the detection result in the detector, and controls a driving force of the source line driver in accordance with the count in the counter.

2. The device according to claim 1, wherein
if the voltage of the source line has exceeded the reference voltage, the controller determines that the number of times of sensing is not less than twice, and
if the count of the ON memory cells is not more than a prescribed value, the controller makes the driving force of the source line driver from the second sensing greater than that in the first sensing.

3. The device according to claim 2, wherein the controller determines that the number of times of sensing is once, if the voltage of the source line has not exceeded the reference voltage.

4. The device according to claim 1, wherein
the source line driver includes a MOS transistor which connects the source line to a first potential, and
the controller controls a gate potential of the MOS transistor.

5. The device according to claim 1, wherein
the source line driver includes:
a plurality of MOS transistors which connect the source line to a first potential, and include gates connected together; and
switching elements which connect the MOS transistors to the source line, and
the controller controls the number of switching elements to be turned on.

6. The device according to claim 1, wherein
the source line driver includes a plurality of MOS transistors which connect the source line to a first potential, and
the controller controls the number of MOS transistors to be turned on.

7. A semiconductor memory device comprising:
a memory cell including a charge accumulation layer and a control gate, and configured to hold data;
a bit line electrically connected to a drain of the memory cell;
a source line electrically connected to a source of the memory cell;
a source line driver which applies a voltage to the source line;
a sense amplifier which reads the data by sensing current flowing through the bit line in a read operation and/or a verify operation of the data;
a counter which counts ON memory cells and/or OFF memory cells in the read operation and/or the verify operation;
a detector which detects whether the voltage of the source line has exceeded a reference voltage, in the read operation and/or the verify operation; and
a controller which controls the number of times of data sensing by the sense amplifier in accordance with the detection result in the detector and the count in the counter, and controls a driving force of the source line driver in accordance with the count in the counter.

8. The device according to claim 7, wherein the controller determines that the number of times of sensing is not less than twice, if the voltage of the source line has exceeded the reference voltage, and
if the voltage of the source line is not more than the reference voltage, and the count of the ON memory cells has exceeded a first prescribed value.

9. The device according to claim 8, wherein the controller makes the driving force of the source line driver from the second sensing greater than that in the first sensing, if the count of the ON memory cells is not more than a second prescribed value.

10. The device according to claim 8, wherein the controller determines that the number of times of sensing is once, if the voltage of the source line is not more than the reference voltage, and the count of the ON memory cells is not more than the first prescribed value.

11. The device according to claim 7, wherein the controller determines that the number of times of sensing is not less than twice, if the voltage of the source line has exceeded the reference voltage, and the count of the ON memory cells has exceeded a first prescribed value.

12. The device according to claim 11, wherein the controller makes the driving force of the source line driver from the second sensing greater than that in the first sensing, if the count of the ON memory cells is not more than a second prescribed value.

13. The device according to claim 11, wherein the controller determines that the number of times of sensing is once, if the voltage of the source line is not more than the reference voltage.

14. The device according to claim 7, wherein the controller determines that the number of times of sensing is not less than twice, if the voltage of the source line is not more than the reference voltage (NO in S10), and the count of the ON memory cells has exceeded a first prescribed value, and
if the voltage of the source line has exceeded the reference voltage, and the count of the ON memory cells has exceeded a second prescribed value.

15. The device according to claim 14, wherein the controller makes the driving force of the source line driver from the second sensing greater than that in the first sensing, if the count of the ON memory cells is not more than a third prescribed value.

16. The device according to claim 14, wherein the controller determines that the number of times of sensing is once, if the voltage of the source line is not more than the reference voltage, and the count of the ON memory cells is not more than the first prescribed value, and
if the voltage of the source line has exceeded the reference voltage, and the count of the ON memory cells is not more than the second prescribed value.

17. A semiconductor memory device comprising:
a memory cell including a charge accumulation layer and a control gate, and configured to hold data;
a bit line electrically connected to a drain of the memory cell;
a source line electrically connected to a source of the memory cell;
a source line driver which applies a voltage to the source line;
a sense amplifier which reads the data by sensing current flowing through the bit line in a read operation and/or a verify operation of the data;
a counter which counts ON memory cells and/or OFF memory cells in the read operation and/or the verify operation;
a detector which detects whether the voltage of the source line has exceeded a reference voltage, in the read operation and/or the verify operation; and
a controller which controls the number of times of data sensing by the sense amplifier and a driving force of the source line driver in accordance with the detection result in the detector and the count in the counter.

18. The device according to claim 17, wherein the controller raises the driving force of the source line driver, if the voltage of the source line has exceeded the reference voltage, and
if the voltage of the source line is not more than the reference voltage, and the count of the ON memory cells is not more than a first prescribed value.

19. The device according to claim 17, wherein the controller raises the driving force of the source line driver, if the voltage of the source line has exceeded the reference voltage, and the count of the ON memory cells is not more than a first prescribed value.

20. The device according to claim 17, wherein the controller raises the driving force of the source line driver, if the voltage of the source line is not more than the reference voltage, and the count of the ON memory cells is not more than a first prescribed value, and
if the voltage of the source line has exceeded the reference voltage, and the count of the ON memory cells is not more than a second prescribed value.
